(19) United States
(12) Patent Application Publication
(10) Pub. No.: US 2002/0073367 A1
(43) Pub. Date: Jun. 13, 2002

(54) Method and integrated circuit for testing a memory having a number of memory banks

(76) Inventor: Udo Hartmann, Munchen (DE)

Correspondence Address: LERNER AND GREENBERG, P.A., Post Office Box 2480, Hollywood, FL, 33022-2480, US

(21) Appl. No.: 09/975,060

(22) Filed: Oct. 11, 2001

(30) Foreign Application Priority Data
Oct. 11, 2000 (DE) 100 50 212.1

(51) Int. Cl. G11C 29/00

(52) U.S. Cl. 714/719

(57) ABSTRACT

A method for testing a memory having a number of memory banks. The process of writing to and/or reading from one of the addressable memory areas of the memory is carried out simultaneously in a number of the memory banks. A test circuit is provided for this purpose, which results in a number of memory bank selection lines being selected simultaneously. Furthermore, a comparator device can be provided for simultaneous reading, which compares the test data items read at the same time and generates a memory status signal if these test data items differ from one another. Even if a fault is found, the comparator device outputs one of the test data items that have been read to the tester device, in order that the tester device can determine the nature of the fault.

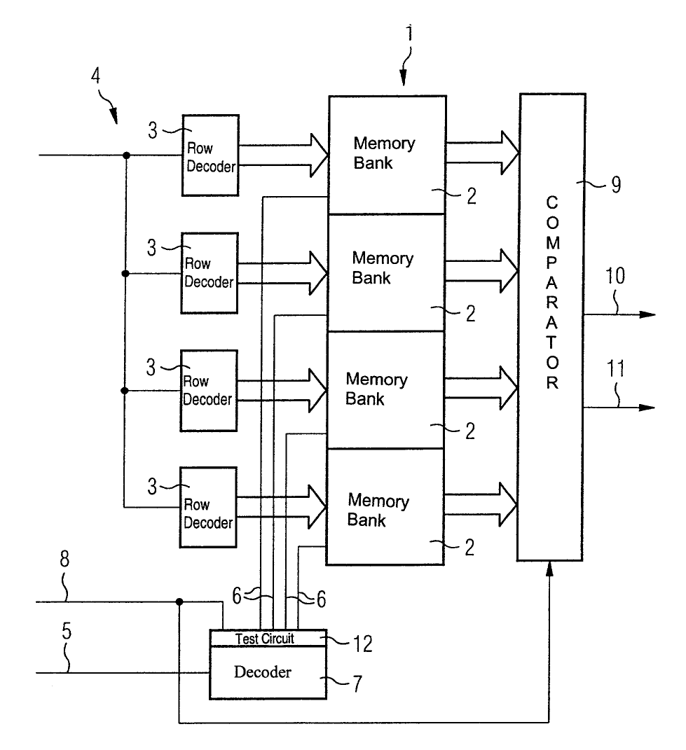

### BACKGROUND OF THE INVENTION

### Field of the Invention

The invention relates to a method and an integrated circuit for testing a memory having a number of memory banks.

When testing the serviceability of memories, test data items are normally written to the memory, and are then read to an external tester again. In the external tester, the data items that have been read are then compared with stored test data items in order to determine whether a memory cell or a memory area is defective. Such a test sequence is normally carried out a number of times with different test data items, which are written to the memory in order to identify different types of possible faults. In this case, the test data items are chosen such that they take account of the physical characteristics of the memory, that is to say, in particular, coupling effects between adjacent lines and/or cells are tested by deliberately writing the same contents, or different contents, to them. The frequent writing and reading during testing of a memory is highly time-consuming, and is thus very costly.

As the integration of memories has progressed, the amount of memory to be tested in a memory module has been increasingly continuously. The bundling of a number of identical memory fields, after their construction, to form what are referred to as memory banks leads, in particular, to the amount of memory which is tested in a test sequence becoming very large.

### SUMMARY OF THE INVENTION

It is accordingly an object of the invention to provide a method and an integrated circuit for testing a memory having a number of memory banks which overcome the above-mentioned disadvantages of the prior art devices and methods of this general type, in which the time for testing a memory having a number of memory banks can be reduced.

With the foregoing and other objects in view there is provided, in accordance with the invention, a method for testing a memory having a number of memory banks each with an addressable memory area. The method includes reading out a stored data item from an addressed memory area in each of the memory banks selected resulting in read data items. The number of the memory banks to be read being selected simultaneously during a test mode such that in each case the stored data item is read simultaneously from jointly addressed memory areas of the memory banks selected. The read data items are then compared with one another. An occurrence of a fault is identified if the stored data item in the addressed memory area of one of the memory banks selected differs from the stored data item in the addressed memory area of a further memory bank selected. In addition, the stored data item stored in one of the memory banks is output to a data output line.

According to the invention, a method is provided for testing a memory having a number of memory banks, which each have an addressable memory area. A stored data item is in each case read from the addressed memory area in the memory banks, with a number of memory banks being selected at the same time in a test mode in order in each case to read a stored data item at the same time from the jointly addressed memory areas in the memory banks selected by the test mode. The stored data items that are read are compared with one another, and with a fault being identified when the stored data item in the memory area of one of the selected memory banks differs from the stored data item in the memory area of a further memory bank. The stored data item stored in one of the memory banks is output to a data output line.

This embodiment has the advantage that the simultaneous activation of a number of memory banks makes it possible to read test data items from the memory banks more quickly.

The stored data items that are read are compared with one another and a fault is confirmed if the stored data item in the memory area in one of the selected memory banks is different to the stored data item in the memory area of a further memory bank. If no difference is found, however, this does not mean that no memory faults are present. This is because it is also possible for a faulty identical stored data item to be stored in all the selected memory banks. For this reason, the invention provides that, in addition to the memory status signal, a data output is also provided in order to output the stored data item, which is stored in one of the memory banks, to the tester device.

It can furthermore be provided for the memory banks each to have a memory area that is addressable. A test data item is written to the addressed memory area in one of the memory banks. Furthermore, a test mode is provided, in which a number of memory banks can be selected at the same time. The test data item can thus be written to the respectively addressed memory area in the selected memory banks.

In the conventional memory configurations in the past, a memory having a number of memory banks is formed, which can be addressed only individually. In a test mode, it is possible to activate a number of memory banks at the same time, in order to write an applied data item simultaneously to the jointly addressed memory areas in the selected memory banks. This is worthwhile since, owing to the identical physical construction of each memory bank, it is sensible to write the same test data items to the memory banks during testing. Thus, the process of writing the data to the memory banks during testing, can be carried out in parallel for a number of memory banks. It is thus possible, during testing, to speed up the process of writing to a memory having a number of memory banks by a factor corresponding to the number of memory banks selected at the same time. This allows the time for testing such a memory to be reduced considerably.

According to one advantageous embodiment, the invention furthermore provides for the test data items that have been read to be compared with one another and for a fault to be confirmed when a test data item in the memory area of one of the selected memory banks differs from that in the memory area of a further memory bank. In this case, it is advantageous for the test data items that are read at the same time actually to be processed in an integrated manner, so that the process of reading the data items from the integrated memory to an external tester does not represent a bottleneck in such a test sequence. It is thus feasible to check whether the test data items that have been read from the addressed memory areas in the selected memory banks are identical. The signal transmitted to the external tester indicates only whether the comparison has resulted in identical or non-identical test data being read.

A further preferred embodiment relating to this provides that, if the comparison shows that the test data items that have been read are identical, the test data items are output to the external tester. Therefore, it is possible to considerably reduce the amount of test data items to be transmitted back to the tester, thus allowing testing time to be saved.

Conventional test methods for memories are normally carried out by the test data items being read successively from the memory to be tested, and then being compared with the respective nominal values. If the value that has been read and the nominal value are not the same, a defective memory cell is identified. In contrast to this, the method according to the invention provides for a number of memory areas in a number of memory banks to be read, and for the contents that have been read to be compared with one another. If the values that have been read are not the same, then at least one of the memory banks contains a defective memory area. This method is less time-consuming than comparing the contents of the respective memory area with the nominal value.

One preferred embodiment furthermore provides a method in which, based on the method according to the invention, the process of writing to and reading from a number of memory banks is to be carried out in one test sequence in each case. Therefore, it is possible to considerably reduce the time for transmitting test data items from and to the tester.

A further aspect of the present invention provides for an integrated test circuit having a memory which has a number of memory banks, with each memory bank having a memory area which can be read and to which a test data item can be written at one address. Furthermore, the integrated circuit has a test circuit, by which a number of memory banks can be activated at the same time. This makes it possible to write the test data item jointly to those memory areas in the selected memory banks that are addressed by that address, and to simultaneously read the respectively stored test data item from the respectively addressed memory areas in the selected memory banks.

A comparator circuit is provided from which the stored test data items of the addressed memory areas in the selected memory banks can be read, with a memory status signal being produced as a function of the test data items that are read, and with the memory status signal indicating whether the test data items that have been read are identical to the addressed memory areas in the selected memory banks. The comparator circuit also has a data output for the test data items that have been read out.

No such device is normally provided in integrated memory modules having a number of memory banks since, for conventional operation of a memory, there is no need to address the memory banks in parallel. The advantage of this invention is thus achieved by selecting a number of memory banks simultaneously for being written to or read from, in order to write the test data items in parallel to those memory areas of the memory banks which are addressed by that address, and then to read the test data items in parallel from the respectively addressed memory area. If a fault is found, one of the test data items is output to the tester device. Furthermore, even if the comparison of the test data items that have been read indicates a fault as a result of the stored test data items not being the same, it is worthwhile outputting the test data items to the tester device in order that the tester device can determine the nature of the faults that have been found.

According to a further preferred embodiment of the invention, a comparator circuit is also provided in the integrated circuit, from which comparator circuit the test data items stored in the addressed memory areas are read from the selected memory banks. A memory status signal is produced as a function of the stored test data items, with provision preferably being made for the memory status signal to be at one logic level when all the output test data items are identical, and to be at a different logic level when at least one test data item, which has been read, of the test data items which have been read is different. This allows a test to be carried out in the integrated circuit itself to identify defective memory areas in the memory banks, covering a large area of faults. In this case, the area of fault coverage becomes larger the greater the number of memory banks that are tested simultaneously using the method according to the invention.

The invention preferably furthermore provides for the comparator circuit to have a data output via which the test data items that have been read from one of the addressed memory areas can be output. This is particularly worthwhile in order to increase the area of fault coverage. The data output can, for example, transmit the test data items that have been read to an external tester, even if the comparison in the comparator circuit shows that the respective memory areas in the selected memory banks have the same contents.

Other features which are considered as characteristic for the invention are set forth in the appended claims.

Although the invention is illustrated and described herein as embodied in a method and an integrated circuit for testing a memory having a number of memory banks, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

The single FIGURE of the drawing is a block diagram of an integrated circuit for testing a memory according to the invention.

### DESCRIPTION OF THE PREFERRED EMBODIMENTS

Referring now to the single FIGURE of the drawing, there is shown a memory 1 having four memory banks 2 of the same size. The four memory banks 2 are addressed by row decoders 3, which are connected to a common address bus 4. In the illustrated exemplary embodiment, the address bus 4 has a width of twelve bits, so that each of the memory banks 2 can be addressed by 4096 row lines. In order to prevent a data item from being written to an addressed memory area in each of the memory banks 2 of the memory 1 during a process of writing to the memory 1, a memory bank selection line 6 is provided for each of the memory banks 2, via which the respective memory bank 2 can be selected. In order to write a data item to an area of the memory 1, there must therefore be an address on the address bus 4, and one of the four memory banks 2 must be selected via the memory bank selection lines 6. The memory bank selection lines 6 are connected so that only one of the memory bank selection lines 6 ever selects a memory bank 2 but not the other memory banks. For this purpose, the memory bank selection lines 6 are connected to a memory bank address line decoder 7. In order to activate four memory bank selection lines 6 in accordance with the described scheme, two memory bank address lines 5 are required, with the four possible states of the memory bank address lines 5 respectively corresponding to the memory bank 2 selected via the memory bank selection lines 6. Therefore, a data item which is intended to be written to a memory area in the memory 1 addressed by the address on the address bus 4 is only ever written to the memory bank 2 as defined by the memory bank address line 5. Furthermore, during conventional operation, there is no provision for a data item to be written to more than one memory bank 2 at the same time.

When testing a memory it is necessary to write data items to the memory and then to read them once again in order, by comparing the written value with the value read out once again, to determine whether the memory contains any defective memory areas. Since the memory banks 2 in the memory 1 are constructed identically and are of the same size, the same data items are written to them in accordance with a predetermined test sequence. In order to speed up the test sequence, the invention now provides for the test data items to be written simultaneously to the respective memory area in each of the memory banks 2 addressed by the address on the address bus 4. Since there is no provision in conventional integrated memory modules in the memory bank address decoder 7 for more than one of the memory bank selection lines 6 to be actuated simultaneously, in order to address a number of the memory banks 2, a test circuit 12 is also provided, which is preferably located in the memory bank address decoder 7 and, according to the invention, is connected to a test mode line 8. The test circuit 12 is activated via the test mode line 8 and causes the memory bank selection lines 6 to be connected, irrespective of the memory bank address applied to the memory bank address line 5, such that all the memory banks 2 are selected and a data item that has been applied for writing is thus written to each memory bank 2 at the address applied to the address bus 4 by the address. It is also, of course, possible to provide for the test mode line 8 to select only a subset of the memory bank selection lines 6, with the respective subset of memory bank selection lines 6 being determined by the memory bank address that is present on the memory bank address line 5.

While, during normal operation of the memory 1, data items, which are addressed by the memory bank address on the memory bank address line 5 and by the address on the address bus 4, in a memory area of the memory 1 are read via a non-illustrated data bus, the data items are applied to a comparator device 9 in the integrated circuit according to the invention. During normal operation of the memory 1, the comparator device 9 applies the data items coming from one of the memory banks 2 to a data output line 10. The comparator device 9 is likewise connected to the test mode line 8. When the test mode line 8 is activated, all the memory banks 2 are actuated, as described above, as a result of which they can be written to simultaneously during a write process, and data items can be read from them, from each of the memory banks 2, simultaneously during a read process, and can be passed to the comparator device 9. In the test mode indicated by the test mode line 8, the comparator device 9 compares the stored data items that have been read with one another. To do this, the comparator device 9 receives from each selected memory bank 2, for example, a data item, previously written in accordance with the method described above, from a memory area addressed by the address on the address line 4. The comparator device 9 compares the data items and sends a fault signal via a memory status line 11 to a non-illustrated test device.

This allows the testing of the memory 1 having a number of the memory banks 2 to be increased considerably, since it is possible to write to the memory banks 2 simultaneously and to read them simultaneously, with a first test actually being carried out in the comparator device 9 during the reading process. The comparator device 9 is preferably provided together with the memory 1 in a common integrated circuit.

Even if it is found, during the comparison of the data items that have been read in the comparison device 9, that the data items stored in the memory banks 2 are identical, it is impossible to preclude the possibility of there still being a systematic fault in the memory 1 which results in all the memory banks 2 in the memory 1 being faulty at one address. For this reason, it is advantageously possible to provide for the data item which is stored in one of the memory banks 2 to be applied, in the test mode indicated by the test mode line 8, to a data output line 10. If the memory status line 11 indicates that different data items are stored in the memory bank 2, it is also possible to provide for the data output line 10 to output a coded status value that indicates the nature of the discrepancy between the data items in the memory banks 2.

The features of the invention disclosed in the above description, in the claims and in the drawing may be significant to the implementation of the invention, in its various embodiments, both individually and in any combination.

I claim:

1. A method for testing a memory having a number of memory banks each with an addressable memory area, which comprises the steps of:
reading out a stored data item from an addressed memory area in each of the memory banks selected resulting in read data items, a number of the memory banks to be read being selected simultaneously during a test mode such that in each case the stored data item is read simultaneously from jointly addressed memory areas of the memory banks selected;
comparing the read data items with one another;
identifying an occurrence of a fault if the stored data item in the addressed memory area of one of the memory banks selected differs from the stored data item in the addressed memory area of a further memory bank selected; and
outputting the stored data item stored in one of the memory banks to a data output line.

2. The method according to claim 1, which comprises:
selecting simultaneously a number of the memory banks during the test mode resulting in jointly addressed memory areas of the memory banks selected; and
writing test data items to the jointly addressed memory areas of the memory banks selected to write the test data item simultaneously to the jointly addressed memory areas in the memory banks selected.

3. The method according to claim 1, which comprises reading the read data items in parallel from the number of the memory banks selected.

4. An integrated circuit, comprising:
a memory having a number of memory banks, each of said memory banks having a memory area which can be read at one address and to which test data items can be written;
a test circuit connected to said memory, said test circuit activating simultaneously a number of said memory banks selected, so that the test data items can be written simultaneously to jointly addressed memory areas in said memory banks selected and the test data items stored can be read simultaneously; and
a comparator circuit connected to said memory and receiving the test data items from said memory, said comparator having a data output from which the test data items of said memory banks selected can be read, said comparator circuit comparing the test data items with each other and generating a memory status signal in dependence on the test data items that are read, the memory status signal indicating whether the test data items that have been read are identical to each other from said memory banks selected.
